(19) United States
(12) Patent Application Publication
(10) Pub. No.: US 2022/0258752 A1
(43) Pub. Date: Aug. 18, 2022

(54) AUTONOMOUS CPS SELF-EVOLUTION FRAMEWORK BASED ON FEDERATED REINFORCEMENT LEARNING FOR PERFORMANCE SELF-EVOLUTION OF AUTONOMOUS CPS AND PERFORMANCE SELF-EVOLUTION METHOD FOR AUTONOMOUS CPS USING THE SAME

(71) Applicant: Korea University Of Technology And Education Indus, Cheonan-si (KR)

(72) Inventors: Won-Tae KIM, Cheonan-si (KR); Deun-Sol CHO, Cheonan-si (KR); Seongjin YUN, Cheonan-si (KR); Hanjin KIM, Cheonan-si (KR); Young-Jin KIM, Cheonan-si (KR)

(73) Assignee: Korea University Of Technology And Education Industry-University Cooperation Foundation, Cheonan-si (KR)

(21) Appl. No.: 17/182,274

(22) Filed: Feb. 23, 2021

(30) Foreign Application Priority Data
Feb. 17, 2021 (KR) 10-2021-0021193

(51) Int. Cl. B60W 50/06; G05D 1/00; B25J 9/16; B60W 60/00; B60W 30/095; B60W 30/182; G05B 13/02

(52) U.S. Cl. CPC B60W 50/06; G05D 1/0088; B25J 9/163; G05B 13/0265; B60W 30/0956; B60W 30/182; B60W 60/001

(57) ABSTRACT

Disclosed is a self-evolution method of an autonomous CPS performance of an autonomous CPS self-evolution framework based on federated reinforcement learning. The method include receiving accident function information, autonomous driving apparatus information, and environment information from an autonomous CPS; configuring at least one distributed dynamics simulation session for simulating actual accident environment and dynamics of an autonomous driving apparatus, based on the accident function information, the autonomous driving apparatus information, and the environment information; training at least one local autonomous control model using the at least one distributed dynamics simulation session, and updating a global autonomous control model based on the at least one trained local autonomous control model; performing performance verification of the global autonomous control model; and when the global autonomous control model meets a performance requirement, updating an autonomous control model of the autonomous CPS to the global autonomous control model.

### BACKGROUND OF THE DISCLOSURE

### Field of the Disclosure

The present disclosure relates to an autonomous CPS self-evolution framework based on reinforcement learning. The present disclosure relates to an autonomous CPS self-evolution framework based on federated reinforcement learning for performance self-evolution of an autonomous CPS, and a performance self-evolution method for the autonomous CPS using the same.

### Related art

A cyber-physical system (CPS) is a system in which a physical system including sensors, actuators, etc. and a computing element for controlling the physical system are intertwined with each other. In other words, in the CPS, 3C, that is, computing, communication, and control, as cyber elements is advanced for intelligence, reliability, safety, and real-time attribute in a legacy embedded system. In recent years, an autonomous cyber-physical system with enhanced autonomy (hereinafter referred to as autonomous CPS) such as autonomous driving cars, autonomous flying drones, and autonomous collaborative robots are capable of performing autonomous situational awareness, decision making, and control without human intervention, beyond a level of intelligence defined in the legacy CPS. The autonomous CPS is composed of a physical system and artificial intelligence-based autonomous control software to perform autonomous situation recognition and determination. Autonomous CPS developers may develop systems based on modeling to perform processes such as dynamic design, simulation, analysis, and verification for systems. The physical system may be implemented as a physical dynamics model that mathematically interprets the physical system and a dynamics control model that controls the analyzed physical dynamics. The autonomous control software may be implemented as an autonomous control model that autonomously recognizes the situation and makes decisions based on artificial intelligence. The physical dynamics model may include a vehicle engine control unit, a vehicle speed control unit, etc. which perform precise control by grasping and calculating a system dynamics relationship. The dynamics control model includes, for example, an electronic control device for a vehicle and a flight control device for a drone to perform stable control of the CPS. Examples of the autonomous control model include ADAS (Advanced Driver Assistance Systems) for autonomous vehicles and drone collision avoidance systems. The autonomous control model recognizes the situation based on the collected sensor information and makes a decision according to the recognized situation. It is important to ensure the reliability of the system as autonomous CPS in safety critical areas may malfunction due to defects in the autonomous control software under circumstances that are not considered during learning, which may harm human safety. Reliability of the autonomous CPS should be guaranteed in a physical dynamics model, a dynamics control model, and an autonomous control model. The physical dynamics model guarantees reliability via a high-precision formula model. The dynamics control model may guarantee reliability via a development and verification method based on function safety standards such as ISO 26262 for automobiles and IEC 62061 for electronic systems. However, an autonomous control model based on artificial intelligence that learns data may not have an authorized reliability verification method thereof and thus it is difficult to guarantee the reliability thereof. Therefore, when developing the system, the reliability of the developed system may not be immediately guaranteed, and thus the insufficient reliability of the developed system must be continuously supplemented via additional procedures.

A general procedure to continuously supplement the reliability of the autonomous control software is as follows. First, defect data in the accident situation as recorded over time are extracted and from the database containing the system status and operation information in the autonomous CPS. Second, the defect data extracted from the autonomous CPS is labeled for learning, and the autonomous control model is trained again using these data. Finally, a reproducible and limited verification scenario is selected and configured in reality, and then performance of a re-trained autonomous control model is evaluated. This procedure allows the autonomous CPS developers to continuously compensate for the reliability of the incomplete autonomous control software.

### SUMMARY

However, the procedure to supplement the reliability of the autonomous control software which has not been established yet has following problems. First, the procedure requires a lot of time and effort for the developers to directly label the extracted data. For example, the developers need to analyze the situation data of an autonomous driving car in which an accident occurred, and input control values at each time step to learn accident prevention. This work is very expensive. Second, since the re-trained autonomous control model performs one-way learning only using the data about the limited accident situation, it is difficult for the developers to consider the causal relationship between data about an accident situation and a behavior determined by the re-trained autonomous control model based on the data. That is, the developer may check whether the trained autonomous control model outputs a correct value at a corresponding time step, using fixed data. However, since there is no situation data that reflects an output value, it may be impossible to verify whether the trained autonomous control model is able to cope with a next situation considering the output value. Third, when performing the evaluation for the autonomous control model within the verification scenario, the evaluation result cannot be trusted due to evaluation indicators that are not objectified and subjective determination of the developer. In other words, performance verification for a corresponding function is not performed, but function verification is performed. The evaluation result value of the function verification may not be an indicator that may objectively evaluate the performance. As a result, the autonomous CPS developers have no choice but to subjectively evaluate that the performance of the autonomous control model has been improved, thereby making the evaluation result unreliable. Due to these problems, there is an increasing need for a technology that guarantees supplementation of the reliability of the autonomous CPS.

Purposes of the present disclosure are not limited to the above-mentioned purpose. Other purposes and advantages of the present disclosure as not mentioned above may be understood from following descriptions and more clearly understood from embodiments of the present disclosure. Further, it will be readily appreciated that the purposes and advantages of the present disclosure may be realized by features and combinations thereof as disclosed in the claims.

One aspect of the present disclosure provides a self-evolution method of an autonomous CPS performance of an autonomous CPS self-evolution framework based on federated reinforcement learning, the method comprising: receiving accident function information, autonomous driving apparatus information, and environment information from an autonomous CPS; configuring at least one distributed dynamics simulation session for simulating actual accident environment and dynamics of an autonomous driving apparatus, based on the accident function information, the autonomous driving apparatus information, and the environment information; training at least one local autonomous control model using the at least one distributed dynamics simulation session, and updating a global autonomous control model based on the at least one trained local autonomous control model; performing performance verification of the global autonomous control model; when the global autonomous control model meets a performance requirement, updating an autonomous control model of the autonomous CPS to the global autonomous control model; or when the global autonomous control model does not meet the performance requirement, re-training the global autonomous control model using the distributed dynamics simulation session.

In one embodiment, the configuring of the at least one distributed dynamics simulation session includes: creating at least one digital twin instance (DTI) corresponding to the autonomous CPS; storing the accident function information, the autonomous driving apparatus information, and the environment information in the at least one digital twin instance; and creating at least one distributed dynamics simulation environment based on the information stored in the at least one digital twin instance.

In one embodiment, the training of the at least one local autonomous control model, and the updating of the global autonomous control model include: distributing the global autonomous control model to the at least one distributed dynamics simulation environment; changing the global autonomous control model to the at least one local autonomous control model and then training the at least one local autonomous control model using reinforcement learning; and sharing a parameter of the at least one local autonomous control model to update the global autonomous control model.

In one embodiment, the sharing of the parameter of the at least one local autonomous control model to update the global autonomous control model includes: applying different weights to the at least one local autonomous control model based on a learning ability of the at least one local autonomous control model; and sharing the parameter of the at least one local autonomous control model to update the global autonomous control model.

In one embodiment, the performing of the performance verification of the global autonomous control model includes inputting a parameter of the global autonomous control model into a performance verification model to verify the performance of the global autonomous control model.

Another aspect of the present disclosure provides an autonomous CPS self-evolution framework based on federated reinforcement learning, the framework comprising: a digital twin management module configured to create a digital twin instance for an autonomous CPS and manage the created digital twin instance; a digital twin instance operating unit for storing the digital twin instance therein; a self-evolution supporting module configured to: perform co-distributed simulation for an accident environment model and a distributed dynamics model for the digital twin instance, based on accident function information, autonomous driving apparatus information, and environment information received from the autonomous CPS; and train an autonomous control model of the autonomous CPS using machine learning based on a distributed simulation result; a performance evolution module configured to: convert the autonomous control model to a local autonomous control model and perform parallel simulation to improve performance of the local autonomous control model; derive a global autonomous control model using a parameter of the local autonomous control model; and re-train the global autonomous control model based on a performance verification result of the global autonomous control model; and a performance verification module configured to: verify the performance of the global autonomous control model; and determine updating of the autonomous control model to the global autonomous control model or re-training of the global autonomous control model, based on the performance verification result.

In one embodiment, the digital twin management module includes: a digital twin service requesting block configured to: when an accident occurs in the autonomous CPS or upon determination that the performance of the global autonomous control model is lower than a reference value, request a performance evolution service to the performance evolution module; request a performance verification service to the performance verification module, when requesting the performance evolution service, provide CPS control model information and CPS operation data related to performance evolution to the performance evolution module; when requesting the performance verification service, provide a performance verification model to the performance verification module; a digital twin instance management block configured to: manage the digital twin instance for the autonomous CPS; and update information specified in the digital twin instance when the performance of the global autonomous control model is improved; a CPS model storage for storing therein the autonomous control model and the dynamics model of the autonomous CPS; a simulation environment storage for storing therein the CPS operation data; and a performance verification model storage for storing therein the verification model for performance evolution of the global autonomous control model.

In one embodiment, the performance evolution module includes: a parallel simulation environment creation block configured to: create at least one simulation environment for training the local autonomous control model; and distribute a first global autonomous control model as a legacy global autonomous control model to the at least one simulation environment to construct the at least one local autonomous control model; a local autonomous control model training block configured to train the at least one local autonomous control model matching the at least one simulation environment based on reinforcement learning and via trial and error data; and a global autonomous control model update/distribution block configured to fuse a parameter of the at least one local trained autonomous control model to update the first global autonomous control model to a second global autonomous control model.

In one embodiment, the global autonomous control model update/distribution block is configured to: apply different weights to the at least one local autonomous control model based on a learning ability of the at least one local autonomous control model; and sharing a parameter of the local autonomous control model to update the first global autonomous control model to the second global autonomous control model.

In one embodiment, the performance verification module includes: a HILS device-simulation association block configured to transmit the global autonomous control model to a HILS target device and execute the HILS target device; an autonomous control model performance verification block configured to perform verification of the global autonomous control model using the performance verification model in a virtual simulation environment and output a quantitative performance evaluation result; and an autonomous CPS update block configured to: identify whether the autonomous control model satisfies a performance requirement, based on the quantitative performance evaluation result; and determine whether to re-train the global autonomous control model depending on whether the autonomous control model satisfies the performance requirement.

In one embodiment, the autonomous CPS update block is configured to: when the global autonomous control model meets the performance requirement, update the digital twin instance, update the autonomous control model of the autonomous CPS to the global autonomous control model; and when the global autonomous control model does not meet the performance requirement, instruct the performance evolution module to retrain the global autonomous control model.

### BRIEF DESCRIPTION OF THE DRAWINGS

Following drawings attached herein illustrate a preferred embodiment of the present disclosure and serves to allow further understanding of the technical idea of the present disclosure along with specific contents for carrying out the disclosure. Thus, the present disclosure is limited to matters described in the drawings.

FIG. 1 shows a service scenario of an autonomous CPS self-evolution framework based on federated reinforcement learning according to an embodiment of the present disclosure.

FIG. 2 shows a configuration of an autonomous CPS self-evolution framework based on federated reinforcement learning according to an embodiment of the present disclosure.

FIG. 3 illustrates a concept of a performance evolution method by a performance evolution module.

FIG. 4 illustrates a concept of a performance verification method by a performance verification module.

FIG. 5 shows a flow of signals between components for updating a control model of an autonomous CPS to a self-evolving control model in a framework according to the present disclosure.

FIG. 6 shows an example of a distributed simulation method by a distributed simulation interpretation engine implemented based on FMI according to an embodiment of the present disclosure.

FIG. 7 shows an example of a performance evolution module based on federated reinforcement learning to improve performance of an autonomous CPS function.

FIG. 8 shows an example of a verification process for a global autonomous control model by a HILS-based performance verification module to verify performance of a autonomous CPS function.

### DESCRIPTION OF EXEMPLARY EMBODIMENTS

The descriptions disclosed herein may be applied to performance self-evolution of the autonomous CPS. However, the descriptions disclosed herein is not limited thereto, and may be applied to all devices and methods to which the technical idea of the descriptions may be applied.

It should be noted that the technical terms used herein are only used to describe a specific embodiment, and are not intended to limit the spirit of the present disclosure. Further, the technical term used herein should be interpreted as meaning generally understood by a person with ordinary knowledge in the field to which the present disclosure belongs, unless otherwise defined herein. The technical term used herein should not be interpreted as excessively comprehensive or excessively reduced meaning. Further, when the technical term used herein is an incorrect technical term that does not accurately express the idea of the present disclosure, a person with ordinary knowledge in the field to which the present disclosure belongs may correctly understand the same and replace the same with a correct term. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Hereinafter, embodiments disclosed herein will be described in detail with reference to the accompanying drawings. Identical or similar constituent elements are denoted by the same reference numerals, and redundant descriptions thereof will be omitted.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

In order to accurately verify an autonomous control model of an autonomous CPS, the autonomous CPS development and verification framework has following requirements. The framework must be able to verify the autonomous CPS based on Hardware-in-the-loop simulation (HILS). Since the framework performs high-precision simulation, a method is required to efficiently use or improve computing resources. Further, a simulation standard interface to increase reusability and extended applications of the model, a data distributed middleware to support fast communication between distributed modules, and a performance verification evaluation index to verify the performance of the autonomous CPS are required.

Federated learning is one of a distributed machine learning techniques, and is a method that trains a model stored in a cloud using each stored data in a distributed learning environment (e.g., a distributed mobile device). Federated reinforcement learning is a new learning method as a combination of federated learning and reinforcement learning. In the federated reinforcement learning method, an agent is distributed to each distributed environment, and each agent performs learning via trial and error with a set purpose. After the learning, the agents may share their intelligence via sharing the gradient and model weight values. In this respect, the federated reinforcement learning method is different from the multi-agent reinforcement learning method in which the agents shares state data with each other, select an individual's action, and share a reward appropriate for the selected result. Further, the federated reinforcement learning method is different from transfer learning of reinforcement learning. Transfer learning not only assumes that state data are shared with each other, but also aims to transfer the experience gained from learning to improve the learning outcomes of the agent. In other words, the federated reinforcement learning has the above differences from the above learning methods because the federated reinforcement learning assumes that the state data may not be shared between agents.

The federated reinforcement learning may effectively obtain a policy for the agent to behave properly under a condition that the state data are not shared between the agents. Further, the federated reinforcement learning may perform partial observation of each agent in the same distributed environment and sharing the observation, such that the federated reinforcement learning may have performance exceeding the performance of DQN as a legacy single reinforcement learning framework.

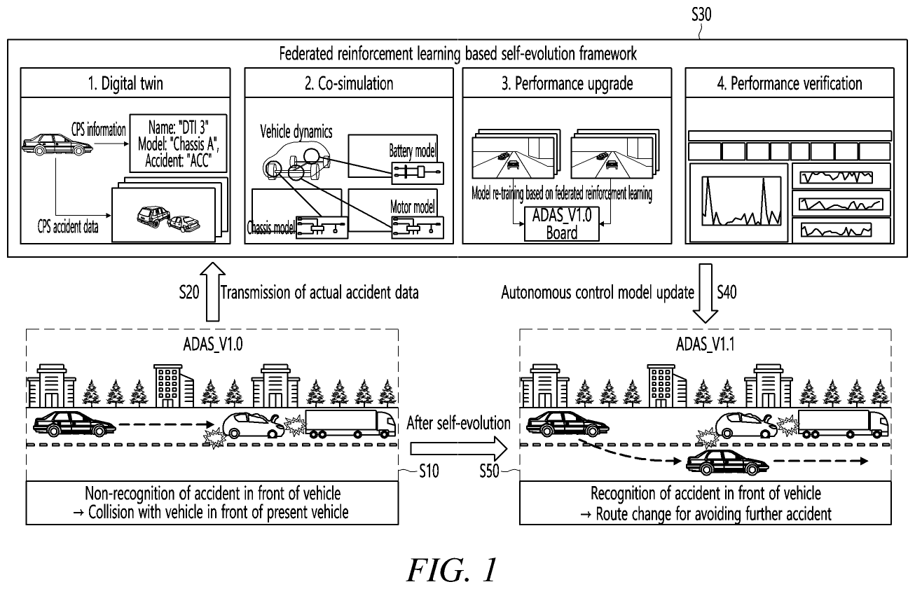

Hereinafter, an autonomous CPS self-evolution framework based on federated reinforcement learning according to an embodiment of the present disclosure and a service operation scenario by the framework will be described with reference to the accompanying drawings FIG. 1 to FIG. 4.

FIG. 1 shows a service scenario of an autonomous CPS self-evolution framework based on federated reinforcement learning according to an embodiment of the present disclosure.

Referring to FIG. 1, the autonomous CPS is operating in the real world using an incomplete autonomous control model, e.g. Advanced Driver Assistance System (ADAS) version 1.0 (ADAS_V1.0). The autonomous CPS with the incomplete autonomous control model does not recognize a vehicle stopped on a road due to an accident in front of the vehicle such that an additional collision occurs (S10).

When the accident occurs, the autonomous CPS transmits accident-related information (e.g., accident function information, vehicle information, environment information) to a self-evolution framework existing in a cloud (S20).

The framework collects accident-related information from the autonomous CPS, and automatically creates a virtual simulation environment based on the collected sensing data. Thereafter, the framework constructs a distributed dynamics simulation session to simulate the dynamics of the actual vehicle based on the collected vehicle information. Thereafter, the framework trains each local autonomous control model via trial and error in the corresponding simulation environment. After the training is completed, the framework updates a global autonomous control model, and performs performance verification for the updated global autonomous control model (S30).

When the global autonomous control model satisfies the performance requirement, the framework updates the autonomous CPS autonomous control model to the evolved global autonomous control model (ADAS_V1.1) (S40).

When the updated global autonomous control model does not meet the performance requirements, the framework may improve the performance of the autonomous control model via the process of re-training and verification until the performance of the global autonomous control model satisfies the requirements.

Finally, based on the evolved autonomous control model (ADAS_V1.1), the autonomous CPS may well recognize another vehicle that has stopped in front of the present vehicle and may prepare countermeasures to avoid the corresponding vehicle (S50).

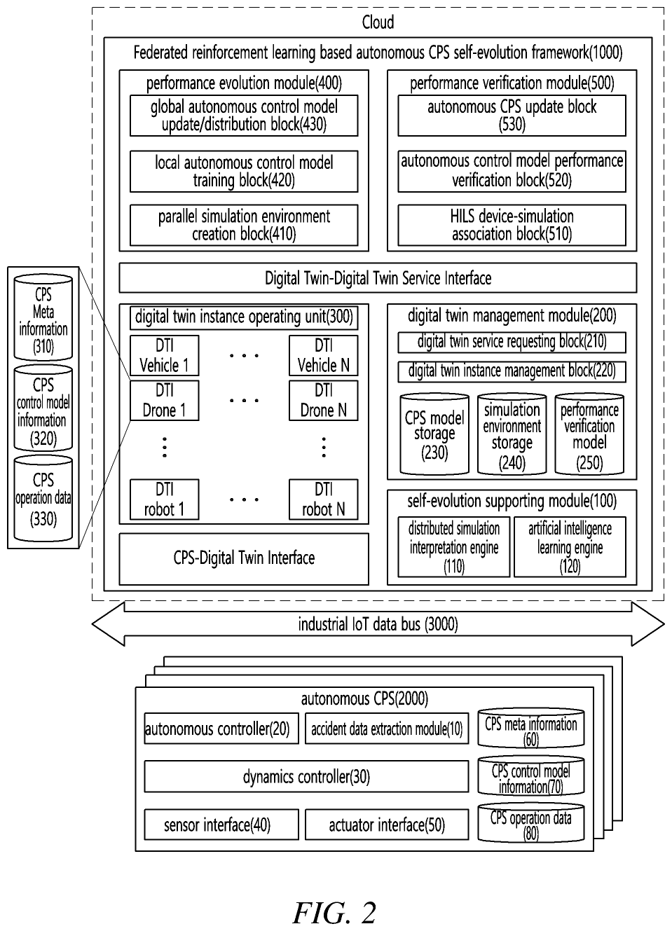

FIG. 2 shows a configuration of an autonomous CPS self-evolution framework based on federated reinforcement learning according to an embodiment of the present disclosure.

Referring to FIG. 2, a framework 1000 according to the embodiment of the present disclosure is configured to include a self-evolution supporting module 100, a digital twin management module 200, a digital twin instance operating unit 300, a performance evolution module 400, and a performance verification module 500. All modules within the framework 1000 may communicate with each other based on a data-centric distribution middleware interface 600 such as DDS (Data Distribution Service) to quickly transmit/receive data in a distributed environment. Data communication between an autonomous CPS 2000 and a digital twin instance (DTI) is performed based on the industrial IoT data bus 3000 that is currently used in the industry. Further, in order to improve the efficiency of computing resources, all operations of the framework 1000 such as digital twin management, performance evolution, and performance verification may be performed in the cloud. In order to reduce the computational complexity in simulating the dynamics model, the dynamics model may be distributed and simulated.

An accident data extraction module 10 in the autonomous CPS 2000 extracts accident-related information when an accident occurs in an actual environment. The accident data extraction module 10 transmits the extracted data to the framework 1000 via the industrial IoT data bus 3000. The framework 1000 stores the data transmitted from the accident data extraction module 10 in a database of a path specified in the digital twin instance.

The self-evolution supporting module 100 is a set of techniques for performing self-evolution. The self-evolution supporting module 100 is composed of a distributed simulation interpretation engine 110 and an artificial intelligence learning engine 120. The distributed simulation interpretation engine 110 may concurrently execute co-distributed simulation for a distributed dynamics model and an environment model for the autonomous CPS 2000, based on the digital twin's CPS meta information and the environment information corresponding to the scenario closest to the accident information selected from the simulation environment storage 240. The distributed simulation interpretation engine 110 includes a master simulator and a slave simulator implemented as FMI (Functional Mock-up Interface) as a representative simulation standard interface. The master simulator is responsible for executing the slave simulator, synchronizing the time, and terminating the slave simulator when performing simulation. Each of the slave simulators may perform simulation using the distributed dynamics model and the environment model. Each slave simulator performs simultaneous simulation while time-synchronizing with other slave simulators at each time step (t) under the management of the master simulator. The distributed simulation interpretation engine 110 provides simulation data about a virtual environment at each time step (t). The artificial intelligence learning engine 120 trains an autonomous control model based on machine learning to improve the performance of the autonomous control model. To implement the artificial intelligence learning engine 120, artificial intelligence libraries such as TensorFlow, Caffe, and PyTorch may be used. Herein, an example in which the TensorFlow library is used to implement reinforcement learning and federated learning will be described.

The digital twin instance operating unit 300 refers to a space where a digital twin instance (DTI) containing various information of the autonomous CPS 2000 connected to the framework 1000 operates. In other words, the digital twin instance refers to a data structure that specifies the information of the connected autonomous CPS 2000. The space storing therein these data structures is the digital twin instance operating unit 300. The digital twin instances in this framework 1000 describes a path of database containing CPS meta information (310) (e.g., autonomous driving vehicle), CPS control model information (320) (e.g., ADAS_V1.0), and CPS operation data 330. When the digital twin management module 200 requests a service (evolution, verification) using digital twin, the digital twin management module 200 may receive information related to the autonomous CPS 2000 via the digital twin instance.

The digital twin management module 200 manages (creates, deletes, modifies) a life cycle of the digital twin instance. When it is determined that performance evolution and performance verification services for the autonomous CPS 2000 are necessary, the digital twin management module 200 requests a related service to each module. The digital twin management module 200 includes a digital twin service requesting block 210, a digital twin instance management block 220, a CPS model storage 230 that stores a CPS control model and a dynamics model, and a simulation environment storage 240 that stores CPS operation data, and a performance verification model storage 250. The digital twin instance management block 220 creates the digital twin instance for the autonomous CPS 2000 when the autonomous CPS 2000 is created. When the autonomous CPS 2000 is discarded, the digital twin instance management block 220 deletes a connected digital twin instance. Further, the digital twin instance management block 220 updates information specified in the digital twin instance when the performance of the autonomous control model of the autonomous CPS 2000 is improved based on the digital twin service. The digital twin service requesting block 210 requests a service to the performance evolution module 400 and the performance verification module 500 when an accident occurs in the autonomous CPS 2000 or when it is determined that performance thereof is insufficient during performance verification. When the digital twin service requesting block 210 requests a service for evolution to the performance evolution module 400, the digital twin service requesting block 210 provides CPS control model information 70 and operation data 80 related to evolution thereto. When the digital twin service requesting block 210 requests a service for verification to the performance verification module 500, the digital twin service requesting block 210 may provide a verification model related to verification of the performance evolution of the autonomous CPS 2000 stored in the performance verification model storage 250 to the performance verification module 500.

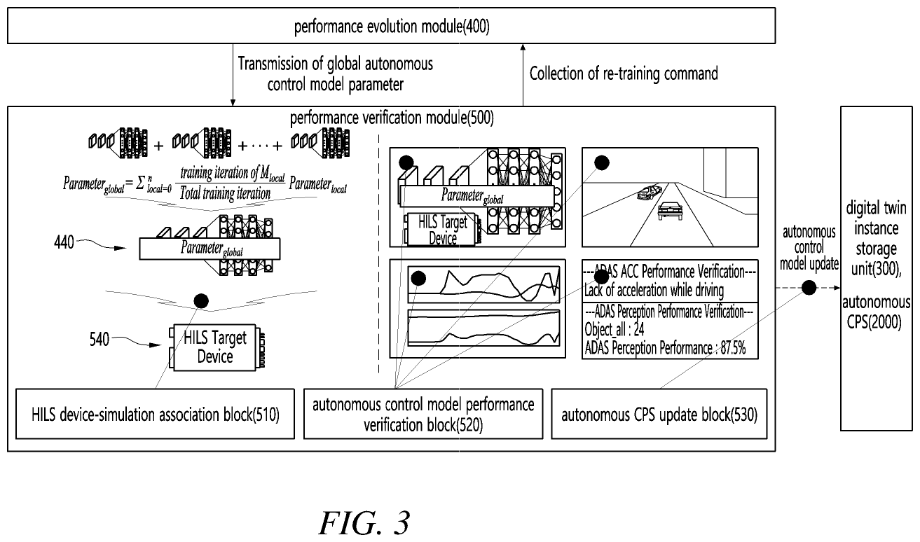

FIG. 3 is a diagram illustrating a concept of the performance evolution method by the performance evolution module 400. Referring to FIG. 3, when an accident occurs or the performance verification module 500 determines that the autonomous control model is incomplete, the performance evolution module 400 may train the incomplete autonomous control model so that its performance may gradually improve. Further, after improving the performance, the performance evolution module 400 requests verification to the performance verification module 500 and performs re-training or terminates the training, based on the performance evaluation result of the performance verification module 500. The performance evolution module 400 may be configured to include a parallel simulation environment creation block 410, a local autonomous control model training block 420, and a global autonomous control model update/distribution block 430 to train the models in a parallel manner.

The parallel simulation environment creation block 410 creates N identical simulation environments (simulation nodes #1 to #N) to train the local autonomous control models, respectively. Thereafter, the global autonomous control model update/distribution block 430 distributes a legacy global autonomous control model to the simulation environments to obtain N local autonomous control models. The local autonomous control model training block (420) trains the autonomous control models matching N environments based on reinforcement learning and via trial and error data. The global autonomous control model update/distribution block 430 updates the legacy global autonomous control model to a new global autonomous control model (440) by fusing parameters of the local models after the training of all of the local autonomous control models has been completed. The global autonomous control model update/distribution block (430) updates the new global autonomous control model by allocating a weight to the local autonomous control model having a high learning ability in order to improve learning efficiency when updating the global autonomous control model.

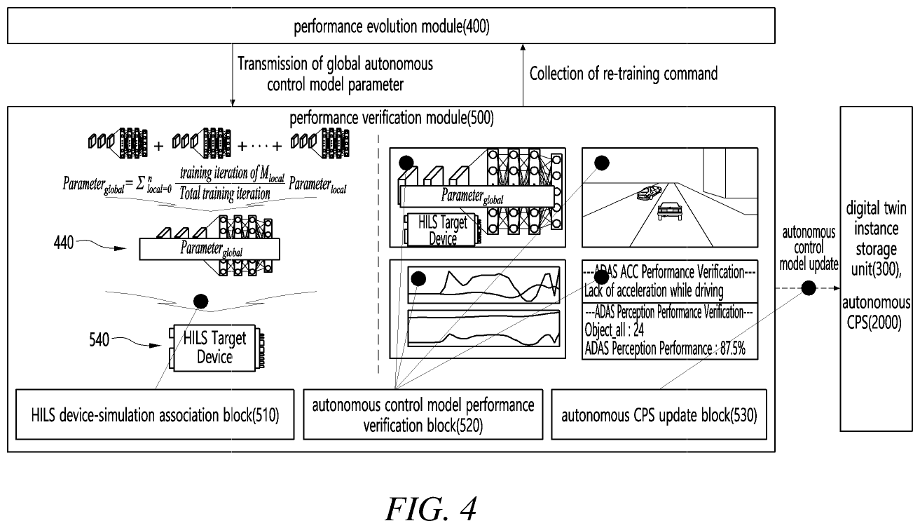

FIG. 4 is a diagram illustrating a concept of the performance verification method by the performance verification module 500. Referring to FIG. 4, the performance verification module 500 verifies the performance of the evolved global autonomous control model and determines whether to update the same to the autonomous CPS 2000 or re-train the same using the performance evolution module 400. The performance verification module 500 may be configured to include an HILS device-simulation association block 510, an autonomous control model performance verification block 520, and an autonomous CPS update block 530. The HILS device-simulation association block 510 transmits the updated global autonomous control model 440 to the HILS target device 540 to be verified, and executes the HILS target device 540. The autonomous control model performance verification block 520 performs verification of the evolved global autonomous control model 440 based on the performance evaluation model in a virtual simulation environment. When the verification is completed, the autonomous control model performance verification block 520 outputs a quantitative performance evaluation result that may objectively verify the performance of the evolved autonomous control model 440. The autonomous CPS update block 530 checks whether the evolved autonomous control model 440 does not meet the performance requirement based on the output quantitative performance evaluation result. When the performance evaluation result does not meet the performance requirement, the autonomous CPS update block 530 issues a command to re-train the global autonomous control model to the performance evolution module 400. When the requirement is satisfied, the autonomous CPS update block 530 updates the digital twin instance using the digital twin management module 200, and transmits the evolved autonomous control model to the autonomous CPS 2000 so that the control model may be updated.

The components of the framework 2000 as described above may be implemented in hardware or software, or may be implemented in a combination of hardware and software.

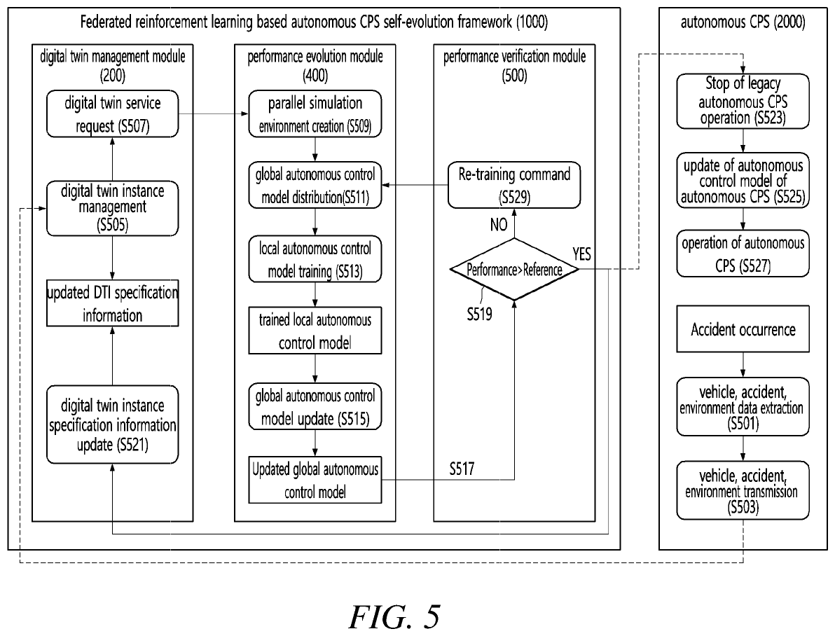

Hereinafter, the self-evolution method of the autonomous CPS control model by the autonomous CPS self-evolution framework based on federated reinforcement learning according to an embodiment of the present disclosure will be described in detail with reference to FIG. 5.

FIG. 5 is a diagram showing the flow of signals between components for updating the autonomous CPS control model to the self-evolving control model in the framework according to the present disclosure. When operating the framework 1000 as disclosed herein, the signals may flow between the autonomous CPS 2000, the digital twin management module 200, the performance evolution module 400, and the performance verification module 500 as shown in FIG. 5.

First, when an accident occurs, the autonomous CPS 2000 extracts data on the vehicle and accident environment via an accident data extraction module (reference number 10 in FIG. 2) (S501). The extracted data is transmitted to the autonomous CPS self-evolution framework 1000 based on federated reinforcement learning (S503). The framework 1000 collects the corresponding data and stores the data in the database of a related path of the digital twin instance operating unit 300, and then creates and manages the digital twin instance (DTI) via the digital twin management module 200 (S505), and requests evolution service and verification service (S507). When the digital twin management module 200 requests the evolution service and the verification service to the performance evolution module 400 and the performance verification module 500, respectively, the digital twin management module 200 transmits, to the performance evolution module 400, the CPS control model (global autonomous control model), and autonomous CPS sensing data in an accident situation to construct a simulation environment to be reproduced, and transmits a verification model that verifies the CPS control model to the performance verification module 500.

Thereafter, the performance evolution module 400 creates N parallel simulation environments for training the local autonomous control models based on the federated reinforcement learning (S509), and distributes the global autonomous control model to the N environments (S511). The performance evolution module 400 converts the distributed global autonomous control model to a local autonomous control model, and then trains the local autonomous control model via reinforcement learning (S513). When training the local autonomous control model is completed, the performance evolution module 400 may allocate a higher weight to the local autonomous control model having a higher learning ability to improve learning efficiency and share parameters to updates the global autonomous control model (S515).

Thereafter, the performance evolution module 400 transmits the parameters of the global autonomous control model to the performance verification module 500 (S517). the performance verification module 500 evaluates the performance by performing verification of the updated global autonomous control model (S519). When the performance of the updated global autonomous control model meets the requirements (i.e., the performance is higher than a reference value), the performance verification module 500 may update the specification information of the digital twin instance via the digital twin management module 200 (S521), and may update the autonomous control model of the autonomous CPS 2000 to the updated global autonomous control model to evolve the autonomous CPS 2000. The updating of the autonomous control model of the autonomous CPS 2000 may include cessation of operation of a legacy autonomous CPS (S523), update of the autonomous control model of the autonomous CPS 2000 (S525), and operation of the autonomous CPS 2000 using the updated autonomous control model (S527) in this order. When the performance of the updated global autonomous control model does not meet the requirements (i.e., the performance is lower than the reference value), the performance verification module 500 issues a re-training command to the performance evolution module 400 (S529), and the performance evolution module 400 performs the distribution (S511) and the training (S513) again.

In the above description, the operations S501 to S529 of the components may be further divided into additional operations or may be combined into fewer operations according to an implementation of the present disclosure. Further, some operations may be omitted when needed, and an order between the operations may vary.

Hereinafter, an embodiment of an autonomous CPS self-evolution framework based on federated reinforcement learning as presented herein will be described. The present disclosure will describe in detail a method that performs a simulation for self-evolution using a distributed simulation model, a method in which an artificial intelligence model of each distributed environment performs reinforcement learning, a method in which each of the distributed simulation nodes considers each decision-making value, and a method that verifies the updated model using a performance verification index.

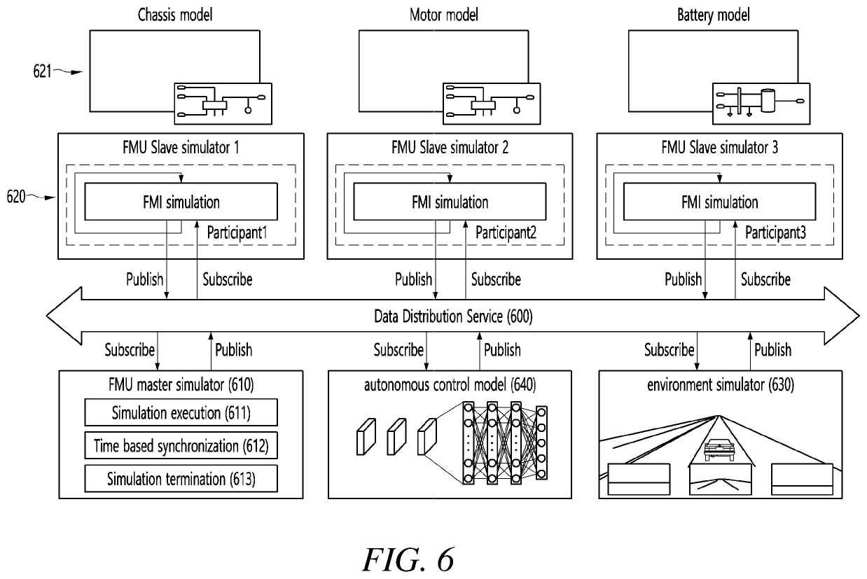

FIG. 6 shows an example of a distributed simulation method by a distributed simulation interpretation engine of the framework implemented based on FMI according to the embodiment of the present disclosure.

According to the present disclosure, simulations for dynamics and environment are executed in a distributed manner to improve the efficiency of computing resources. The distributed simulation interpretation engine 110 of the self-evolution supporting module 100 in the framework 1000 according to the embodiment of the present disclosure forms a structure as shown in FIG. 6 when performing distributed simulation. The distributed simulation is composed of a FMU (Functional Mock-up Units) master simulator 610, a plurality of FMU slave simulators 620, an environment simulator 630, and an autonomous control model 640. When performing distributed simulation, the DDS 600 is used to exchange a large amount of data in the distributed environment. The FMU master simulator 610 performs simulation execution (611), time synchronization for simultaneous simulation (612), and simulation termination (613). While the FMU master simulator 610 regards the environment simulator 630 and the autonomous control model 640 (e.g., ADAS) as a slave simulator, the FMU master simulator 610 performs simultaneous simulation. The FMU slave simulator 620 may refer to a distributed dynamics model 621 that may be associated with the motor, chassis, and battery of a vehicle. When the FMU master simulator 610 executes the simulation, the simultaneous simulation is performed while several FMUs are associated with each other via DDS using a model solver built into each FMU slave simulator 620. The FMU slave simulators 620 perform FMI simulation simultaneously in accordance with a time synchronization command 612 of the FMU master simulator 610.

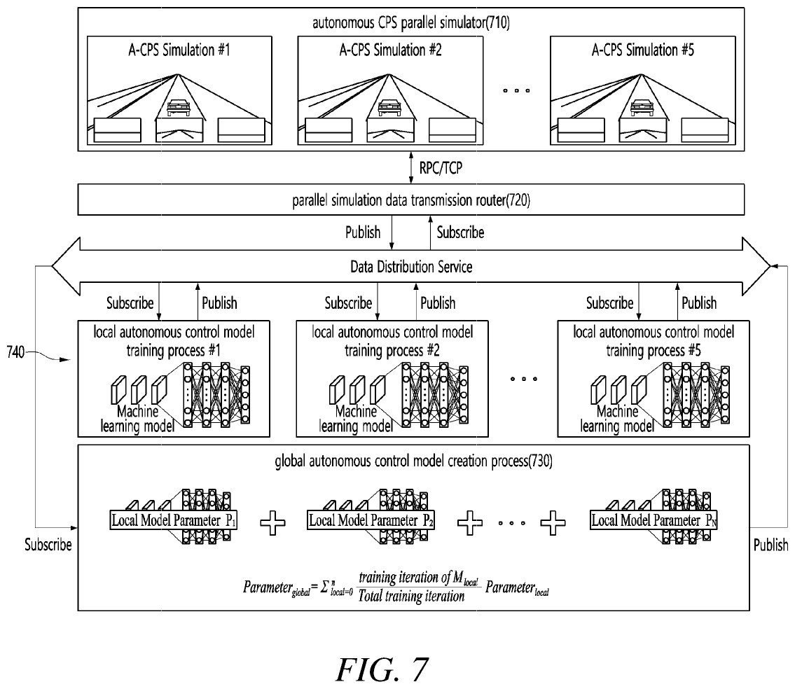

FIG. 7 shows an example of a performance evolution module based on federated reinforcement learning to improve the performance of an autonomous CPS function.

The performance evolution module 400 of the framework 1000 as disclosed herein forms a structure as shown in FIG. 7 when training the local autonomous control models to perform training/re-training. In order to perform the training of the local autonomous control model, the autonomous CPS parallel simulator 710 may equally construct the autonomous CPS simulation environments in the distributed manner. The autonomous CPS simulations (A-CPS Simulation #1 to #5) of the parallel simulators 710 are based on the distributed simulation in FIG. 6. In order to transmit the simulation data of the simulation nodes to an external component, the parallel simulation data transmission router 720 collects simulation data (sensor, dynamics data) of the simulation nodes at each time step (t) and structures and publishes the collected data as a DDS topic.

The reinforcement learning process by the performance evolution module 400 is a process of training each of the local artificial intelligence models based on reinforcement learning. At each time step (t), the performance evolution module 400 subscribes to the DDS topic of a simulation node related to each training. The reinforcement learning process may train a machine learning model using the subscribed data, and may create autonomous CPS decision values in the simulation node via real-time inference. In the reinforcement learning process, the corresponding data is structured and published as a DDS topic in order to input the real-time inference results of the machine learning model into the simulation node of each autonomous CPS. Each parallel simulation data transmission router 720 subscribes to the machine learning inference results at each time step (t) and transmits the results to the related simulation node. The autonomous CPS parallel simulator 710 collects data from the parallel simulation data transmission router 720 at each time step (t) and performs the simulation by inputting the determined behavior value to the dynamics of the autonomous CPS. Whenever an episode of reinforcement learning reaches weight update time as a hyper parameter of federated reinforcement learning, the global autonomous control model creation process 730 subscribes to the parameters of the autonomous control model in the local autonomous control model training processes 740, and allocates a weight based on a learning ability thereto, and updates the global autonomous control model using the parameters of the local autonomous control model, and publishes the topic to each local autonomous control model training process 740 to distribute the weight of the global autonomous control model.

According to the present disclosure, the federated reinforcement learning method configured to include the local autonomous control model performance evolution process, the global autonomous control model update process, and the global autonomous control model performance verification process is performed to train a deep learning model. The performance evolution process trains the model using a state, action, next state, and reward based on reinforcement learning for each local deep learning model. Further, the real-time inference data of the deep learning model is transmitted to the simulator and reflected toward the simulation result. The global deep learning model is updated by sharing the weights of the trained local deep learning models at each updating step of the weight set as a hyper parameter. At this time, in order to increase the learning efficiency, weights may be allocated and shared based on the amount of data which the local deep learning model has learned. When the updated global deep learning model satisfies the specified performance requirement, the corresponding model is updated to the autonomous CPS. When the performance requirement is not satisfied, the model is transmitted to the performance evolution process again in which re-training thereof is performed. In this way, not only the reinforcement learning score is checked but also additional performance verification in a predetermined scenario is performed, such that the reliability of the deep learning model is secured. When continuously training the model until the model satisfies the performance requirement, autonomous performance improvement of the deep learning model may be achieved. Further, fusing the features of the model trained via the reinforcement learning based on federated learning may achieve fast performance improvement and high performance safety.

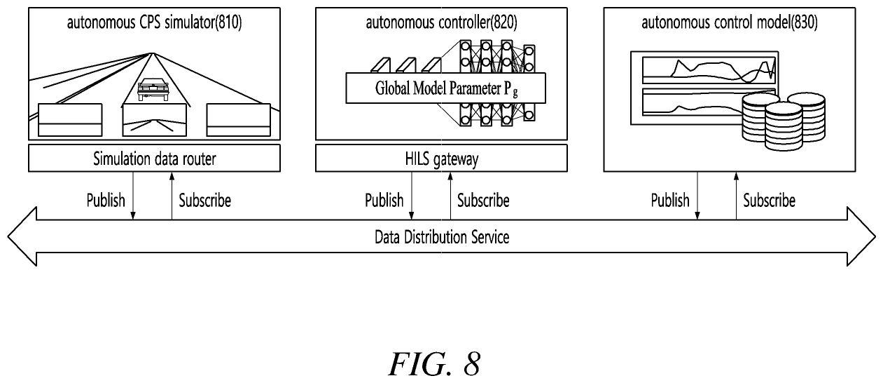

FIG. 8 shows an example of the verification process of the global autonomous control model by the HILS-based performance verification module to verify the performance of the autonomous CPS function.

The performance verification module 500 of the framework 1000 as disclosed herein forms a structure as shown in FIG. 8 when verifying the updated global autonomous control model. The performance verification module 500 transmits the global autonomous control model 830 updated by the performance evolution module 400 to the HILS controller 820. Thereafter, in order to verify the global autonomous control model 830, the framework 1000 may construct the verification environment of the corresponding model. In order to check whether the model performs the mission well when the model is mounted on a controller which will actually operate, simultaneous simulation is performed on the autonomous CPS simulator 810 and the controller 820 based on HILS, and then the simulation data is published as DDS topic. The performance verification module 500 subscribes to the DDS topic to collect simulation data, and verifies the collected data based on the performance evaluation index. After completing the functional performance evaluation of the autonomous CPS, the performance verification module 500 publishes the verification result as a DDS topic so that the autonomous CPS developer may check the result. The ADAS as an example of the autonomous control model as set forth herein may have a function that supports the driver's perception and a function that performs direct control of the vehicle. When performing the function that supports the driver's perception, the vehicle is directly controlled by a person, so that the function does not significantly affect safety. However, since a function that performs the direct control of the vehicle leads to an accident under an incorrect determination, the function may cause great harm to human safety. According to the present disclosure, in order to perform precise performance verification of an ACC (Adaptive Cruise Control) that performs direct control of the vehicle and may harm human safety, a performance evaluation index is designed and used for evaluation.

The deep reinforcement learning method and the federated reinforcement learning method may be applied to train a deep learning model for an ACC time difference control mode in which a distance to a vehicle in front of the present vehicle is detected and the vehicle is controlled based on the distance among control modes of the ACC. Then, the training results may be compared with each other. Thus, when only the deep reinforcement learning is applied thereto, it may take a lot of time until the performance has been stabilized. However, when the federated reinforcement learning is applied to the model, it may take a smaller time until the performance has been stabilized.

Although the federated reinforcement learning method updates the global deep learning model by sharing the weights of the local models at every weight update time and distributes the updated weights equally to all of the local deep learning models, the performances of the local deep learning models may be different from each other. This is because even though the local deep learning models have the same parameter at each weight update time, the models are subsequently trained in real time based on the reinforcement learning, and, in this connection, the trial and error data (state, action, next_state, reward) learned by the local deep learning models are different from each other, such that the updated weights of the models are different from each other. However, this indicates that the global deep learning model may fuse the different weights of the local deep learning models to flexibly cope with the data learned by the local deep learning models. In other words, the global deep learning model may obtain collective intelligence that may extract the features of the learned data from the local deep learning models.

In the legacy deep reinforcement learning, when the trial and error data is biased because data of other entities may not be considered, the model itself may not be trained well. However, in the federated reinforcement learning according to the embodiment of the present disclosure, the same effect as learning the data of other entities by the model each time the local deep learning model is updated may be obtained. Thus, the shortcomings of the deep reinforcement learning may be solved. Further, in the federated reinforcement learning according to the embodiment of the present disclosure, when the local models are fused into the global model, a new model parameter is created and a search for a new area is performed. Thus, various training data may be extracted, such that the model may be trained more quickly. Thus, the federated reinforcement learning method according to the embodiment of the present disclosure allows each local deep learning model to quickly learn features learned from other entities, thereby improving the performance faster than the legacy reinforcement learning method does.

In the above embodiments, an autonomous driving car has been exemplified as an example of an autonomous driving device. In addition to autonomous driving cars, the present disclosure may be applied to any device that has an autonomous control function, such as an autonomous flying drone or an autonomous operating robot.

In order to solve the problem of the labeling task that the autonomous CPS developers perform manually to train the autonomous control model, the framework according to the embodiment disclosed herein may construct identically distributed simulation environments that simulate an accident environment and apply and operate a local autonomous control model to each simulation environment to automatically extract trial-and-error data and compensation values that may be learned.

Further, in order to solve the problem of performing one-way learning using conventional limited situation data, the framework according to the embodiment disclosed herein may apply the reinforcement learning to each of the local autonomous control models placed in distributed simulation environments so that the autonomous control model may autonomously learn a response scheme in consideration of the continuous causal relationship in an accident situation, thereby to preform real-time two-way learning. In order to improve learning efficiency, the high weight may be applied to the local autonomous control model having a higher learning ability, and the parameters of the models may be shared based on the federated reinforcement learning method, thereby updating the global autonomous control model.

Further, the framework according to the embodiment disclosed herein performs the performance verification of the global autonomous control model via simulation within an evaluation scenario that may not be reproduced in reality. The verification may be performed based on a quantitative performance evaluation index that may objectify performance in terms of the function safety standard to ensure the reliability of the performance evaluation result.

Further, the framework according to the embodiment disclosed herein may perform a procedure including the distribution of the global autonomous control model to the distributed simulation environments, and the local autonomous control model re-training, the global autonomous control model update, and the global autonomous control model verification until the performance requirements are satisfied, so that the performance of the configured global autonomous control model meets the quantified evaluation requirements.

Further, the framework according to the embodiment disclosed herein has the effect of self-evolution of the autonomous control model while performing precise performance verification for the autonomous control model.

Further, the effects that may be obtained from the present disclosure are not limited to the effects mentioned above. Other effects not mentioned may be clearly understood by those of ordinary skill in the technical field to which the present disclosure belongs from the above descriptions.

The term “unit” used herein (e.g., a control unit, etc.) may mean, for example, a unit including one or a combination of two or more of hardware, software, or firmware. “Unit” may be used interchangeably with terms such as unit, logic, logical block, component, or circuit, for example. The “unit” may be a minimum unit of an integra part or a portion thereof. The “unit” may be a minimum unit performing one or more functions, and a portion thereof. The “unit” may be implemented mechanically or electronically. For example, the “unit” may include at least one of application-specific integrated circuit (ASIC) chips, field-programmable gate arrays (FPGAs), or programmable-logic devices that perform certain operations and are currently known or will be developed in the future.

At least a portion of a device (e.g., modules or functions thereof) or a method (e.g., operations) according to various embodiments may be implemented using instructions stored in, for example, a computer-readable storage media in the form of a program module. When the instructions are executed by a processor, the one or more processors may perform a function corresponding to the instruction. The computer-readable storage medium may be, for example, a memory.

The computer-readable storage media/computer-readable recording media may include hard disks, floppy disks, magnetic media (e.g., magnetic tape), optical media (e.g., CD-ROM (compact disc read only memory), DVD (digital versatile disc), magnetic-optical media (e.g. floptical disk), hardware devices (e.g., read only memory (ROM), random access memory (RAM), or flash memory), etc. Further, the program instruction may include a high-level language code that may be executed by a computer using an interpreter or the like as well as a machine language code created by a compiler. The above-described hardware device may be configured to operate as one or more software modules to perform operations of various embodiments, and vice versa.

A module or a program module according to various embodiments may include at least one or more of the above-described elements, some of them may be omitted therefrom, or the module or program module may further include additional other elements. Operations performed by a module, a program module, or other components according to various embodiments may be executed in a sequential, parallel, repetitive, or heuristic manner. Further, some operations may be executed in a different order, omitted, or other operations may be added thereto.

As used herein, the singular forms “a”, “an”, and “one” are intended to include the plural forms as well, unless the context clearly indicates otherwise. It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The arrangement of components to achieve the same function is effectively “related” so that the desired function is achieved. Thus, any two components combined to achieve a particular function may be considered to be “related” to each other such that the desired function is achieved, regardless of a structure or am intervening component. Likewise, two components thus related may be considered to be “operably connected” or “operably coupled” to each other to achieve the desired function.

Further, one of ordinary skill in the art will recognize that a boundary between the functionalities of the aforementioned operations is merely exemplary. A plurality of operations may be combined into a single operation. A single operation may be divided into additional operations. Operations may be executed in an at least partially overlapping manner in time. Further, alternative embodiments may include a plurality of instances of a specific operation. The order of operations may vary in various other embodiments. However, other modifications, variations and alternatives may be present. Accordingly, the detailed description and drawings should be regarded as illustrative and not restrictive.

The phrase “may be X” indicates that the condition X may be satisfied. This phrase also indicates that condition X may not be satisfied. For example, a reference to a system that contains a specific component should also include a scenario where the system does not contain the specific component. For example, a reference to a method containing a specific operation should also include a scenario where the corresponding method does not contain the specific operation. However, in another example, a reference to a system configured to perform a specific operation should also include a scenario where the system is configured not to perform the specific operation.

The terms “comprising”, “having”, “composed of”, “consisting of” and “consisting essentially of” are used interchangeably. For example, any method may include at least an operation included in the drawing and/or specification, or may include only an operation included in the drawings and/or specification.

Those of ordinary skill in the art may appreciate that the boundaries between logical blocks are merely exemplary. It will be appreciated that alternative embodiments may combine logical blocks or circuit elements with each other or may functionally divide various logical blocks or circuit elements. Therefore, a architecture shown herein is only exemplary. In fact, it should be understood that various architectures may be implemented that achieve the same function.

Further, for example, in one embodiment, the illustrated examples may be implemented on a single integrated circuit or as a circuit located within the same device. Alternatively, the examples may be implemented as any number of individual integrated circuits or individual devices interconnected with each other in a suitable manner. Other changes, modifications, variations and alternatives may be present. Accordingly, the specification and drawings are to be regarded as illustrative and not restrictive.

Further, for example, the examples or some of thereof may be implemented using physical circuits such as any suitable type of hardware description language, or software or code representations of logical representations convertible to physical circuits.

Further, the present disclosure is not limited to a physical device or unit implemented as non-programmable hardware, but may be applied to a programmable device or unit capable of performing a desired device function by operating according to an appropriate program code, such as a main frame generally referred to as a ‘computer system’, a mini computer, server, workstation, personal computer, notepad, PDA, electronic game player, automobiles and other embedded systems, mobile phones and various other wireless devices, etc.

A system, device or device mentioned herein may include at least one hardware component.

Connection as described herein may be any type of connection suitable for transmitting a signal from or to each node, unit or device via an intermediate device, for example. Thus, unless implied or otherwise stated, the connection may be direct connection or indirect connection, for example. Connection may include single connection, multiple connection, one-way connection or two-way connection. However, different embodiments may have different implementations of the connection. For example, separate one-way connection may be used rather than two-way connection, and vice versa. Further, a plurality of connections may be replaced with a single connection in which a plurality of signals are transmitted sequentially or in a time multiplexing scheme. Likewise, a single connection in which a plurality of signals are transmitted may be divided into various connections in which subsets of the signals are transmitted. Thus, there are many options for transmitting the signal.

In the claims, any reference signs placed between parentheses shall not be construed as limiting the claim. The word ‘comprising’ does not exclude the presence of elements or operations listed in a claim.

In the above descriptions, the preferred embodiments of the present disclosure have been described with reference to the accompanying drawings. The terms or words used herein and claims should not be construed as being limited to a conventional or dictionary meaning, and should be interpreted as a meaning and concept consistent with the technical idea of the present disclosure. The scope of the present disclosure is not limited to the embodiments disclosed herein. The present disclosure may be modified, altered, or improved in various forms within the scope of the spirit and claims of the present disclosure.

what is claimed is:

1. A self-evolution method of an autonomous CPS performance of an autonomous CPS self-evolution framework based on federated reinforcement learning, the method comprising:
receiving accident function information, autonomous driving apparatus information, and environment information from an autonomous CPS;
configuring at least one distributed dynamics simulation session for simulating actual accident environment and dynamics of an autonomous driving apparatus, based on the accident function information, the autonomous driving apparatus information, and the environment information;
training at least one local autonomous control model using the at least one distributed dynamics simulation session, and updating a global autonomous control model based on the at least one trained local autonomous control model;
performing performance verification of the global autonomous control model;
when the global autonomous control model meets a performance requirement, updating an autonomous control model of the autonomous CPS to the global autonomous control model; or
when the global autonomous control model does not meet the performance requirement, re-training the global autonomous control model using the distributed dynamics simulation session.

2. The method of claim 1, wherein the configuring of the at least one distributed dynamics simulation session includes:
creating at least one digital twin instance (DTI) corresponding to the autonomous CPS;
storing the accident function information, the autonomous driving apparatus information, and the environment information in the at least one digital twin instance; and
creating at least one distributed dynamics simulation environment based on the information stored in the at least one digital twin instance.

3. The method of claim 1, wherein the training of the at least one local autonomous control model, and the updating of the global autonomous control model include:
distributing the global autonomous control model to the at least one distributed dynamics simulation environment;
changing the global autonomous control model to the at least one local autonomous control model and then training the at least one local autonomous control model using reinforcement learning; and
sharing a parameter of the at least one local autonomous control model to update the global autonomous control model.

4. The method of claim 3, wherein the sharing of the parameter of the at least one local autonomous control model to update the global autonomous control model includes:
applying different weights to the at least one local autonomous control model based on a learning ability of the at least one local autonomous control model; and
sharing the parameter of the at least one local autonomous control model to update the global autonomous control model.

5. The method of claim 1, wherein the performing of the performance verification of the global autonomous control model includes inputting a parameter of the global autonomous control model into a performance verification model to verify the performance of the global autonomous control model.

6. An autonomous CPS self-evolution framework based on federated reinforcement learning, the framework comprising:
a digital twin management module configured to create a digital twin instance for an autonomous CPS and manage the created digital twin instance;
a digital twin instance operating unit for storing the digital twin instance therein;
a self-evolution supporting module configured to:
perform co-distributed simulation for an accident environment model and a distributed dynamics model for the digital twin instance, based on accident function information, autonomous driving apparatus information, and environment information received from the autonomous CPS; and
train an autonomous control model of the autonomous CPS using machine learning based on a distributed simulation result;
a performance evolution module configured to:
convert the autonomous control model to a local autonomous control model and perform parallel simulation to improve performance of the local autonomous control model;
derive a global autonomous control model using a parameter of the local autonomous control model; and
re-train the global autonomous control model based on a performance verification result of the global autonomous control model; and
a performance verification module configured to:
verify the performance of the global autonomous control model; and
determine updating of the autonomous control model to the global autonomous control model or re-training of the global autonomous control model, based on the performance verification result.

7. The framework of claim 6, wherein the digital twin management module includes:
a digital twin service requesting block configured to:
when an accident occurs in the autonomous CPS or upon determination that the performance of the global autonomous control model is lower than a reference value, request a performance evolution service to the performance evolution module;
request a performance verification service to the performance verification module,
when requesting the performance evolution service, provide CPS control model information and CPS operation data related to performance evolution to the performance evolution module;
when requesting the performance verification service, provide a performance verification model to the performance verification module;
a digital twin instance management block configured to:
manage the digital twin instance for the autonomous CPS; and
update information specified in the digital twin instance when the performance of the global autonomous control model is improved;
a CPS model storage for storing therein the autonomous control model and the dynamics model of the autonomous CPS;
a simulation environment storage for storing therein the CPS operation data; and
a performance verification model storage for storing therein the verification model for performance evolution of the global autonomous control model.

8. The framework of claim 6, wherein the performance evolution module includes:
a parallel simulation environment creation block configured to:
create at least one simulation environment for training the local autonomous control model; and
distribute a first global autonomous control model as a legacy global autonomous control model to the at least one simulation environment to construct the at least one local autonomous control model;
a local autonomous control model training block configured to train the at least one local autonomous control model matching the at least one simulation environment based on reinforcement learning and via trial and error data; and
a global autonomous control model update/distribution block configured to fuse a parameter of the at least one local trained autonomous control model to update the first global autonomous control model to a second global autonomous control model.

9. The framework of claim 8, wherein the global autonomous control model update/distribution block is configured to:
apply different weights to the at least one local autonomous control model based on a learning ability of the at least one local autonomous control model; and
share a parameter of the local autonomous control model to update the first global autonomous control model to the second global autonomous control model.

10. The framework of claim 6, wherein the performance verification module includes:
a HILS device-simulation association block configured to transmit the global autonomous control model to a HILS target device and execute the HILS target device;
an autonomous control model performance verification block configured to perform verification of the global autonomous control model using the performance verification model in a virtual simulation environment and output a quantitative performance evaluation result; and
an autonomous CPS update block configured to:
identify whether the autonomous control model satisfies a performance requirement, based on the quantitative performance evaluation result; and
determine whether to re-train the global autonomous control model depending on whether the autonomous control model satisfies the performance requirement.

11. The framework of claim 10, wherein the autonomous CPS update block is configured to:
when the global autonomous control model meets the performance requirement, update the digital twin instance, update the autonomous control model of the autonomous CPS to the global autonomous control model; and
when the global autonomous control model does not meet the performance requirement, instruct the performance evolution module to retrain the global autonomous control model.
